(19) United States
(12) Patent Application Publication
(10) Pub. No.: US 2026/0271394 A1
(43) Pub. Date: Sep. 10, 2026

(54) MEDIUM-VOLTAGE FIN-TYPE FIELD-EFFECT TRANSISTORS

(71) Applicant: GlobalFoundries U.S. Inc., Malta, NY (US)

(72) Inventors: Man Gu, Malta, NY (US); Haiting Wang, Clifton Park, NY (US)

(21) Appl. No.: 19/070,753

(22) Filed: Mar. 5, 2025

(51) Int. Cl. H10D 84/85; H10D 30/01; H10D 62/10; H10D 64/68; H10D 84/01

(52) U.S. Cl. CPC H10D 84/853; H10D 30/0245; H10D 62/102; H10D 62/124; H10D 64/681; H10D 84/0179; H10D 84/0193; H10D 84/856

(57) ABSTRACT

Device structures for a medium-voltage fin-type field-effect transistor and methods of forming such device structures. The structure comprises a field-effect transistor including a semiconductor fin, a first source/drain region, a second source/drain region, a gate that wraps around the semiconductor fin, and a gate dielectric layer between the gate and the semiconductor fin. The gate dielectric layer includes a first dielectric layer and a second dielectric layer on the first dielectric layer, and the gate is laterally positioned between the first source/drain region and the second source/drain region.

### BACKGROUND

The disclosure relates to semiconductor device fabrication and integrated circuits and, more specifically, to device structures for a medium-voltage fin-type field-effect transistor and methods of forming such device structures.

Complementary-metal-oxide-semiconductor processes may be used to build a combination of p-type and n-type field-effect transistors that are used to construct, for example, logic cells. Field-effect transistors generally include a channel region in a substrate, a source, a drain, and a gate structure over the channel region. When a control voltage exceeding a characteristic threshold voltage is applied to a gate electrode of the gate structure, carrier flow occurs in the channel region between the source and the drain to produce a device output current.

A fin-type field-effect transistor is a non-planar device structure that may be more densely packed in an integrated circuit than a planar field-effect transistor. A fin-type field-effect transistor may include a fin, gate structures that overlap with different portions of the fin, and source/drain regions arranged between the gate structures. The source/drain regions may be epitaxially grown inside cavities that are etched in the fin.

Planar field-effect transistors may be configured to operate at a medium voltage, such as a voltage with a range of eight volts to ten volts, that is higher than the operational voltage range for a fin-type field-effect transistor. Medium-voltage planar field-effect transistors cannot be integrated into a process flow forming low-voltage fin-type field-effect transistors without significant alterations to the process flow.

Improved device structures for a medium-voltage fin-type field-effect transistor and methods of forming such device structures are needed.

### SUMMARY

In an embodiment of the invention, a structure comprises a field-effect transistor including a semiconductor fin, a first source/drain region, a second source/drain region, a gate that wraps around the semiconductor fin, and a gate dielectric layer between the gate and the semiconductor fin. The gate dielectric layer includes a first dielectric layer and a second dielectric layer on the first dielectric layer, and the gate is laterally positioned between the first source/drain region and the second source/drain region.

In an embodiment of the invention, a method comprises forming a field-effect transistor including a semiconductor fin, a first source/drain region, a second source/drain region, a gate that wraps around the semiconductor fin, and a gate dielectric layer between the gate and the semiconductor fin. The gate dielectric layer includes a first dielectric layer and a second dielectric layer on the first dielectric layer, and the gate is laterally positioned between the first source/drain region and the second source/drain region.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 is a top view of a structure at an initial fabrication stage of a processing method in accordance with embodiments of the invention.

FIG. 2 is a cross-sectional view taken generally along line 2-2 in FIG. 1.

FIG. 2A is a cross-sectional view taken generally along line 2A-2A in FIG. 1.

FIG. 2B is a cross-sectional view taken generally along line 2B-2B in FIG. 1.

FIGS. 3, 3A, 3B are cross-sectional views of the structure at a fabrication stage of the processing method subsequent to FIGS. 1, 2, 2A, 2B.

FIGS. 4, 4A, 4B are cross-sectional views of the structure at a fabrication stage of the processing method subsequent to FIGS. 3, 3A, 3B.

FIGS. 5, 5A, 5B are cross-sectional views of the structure at a fabrication stage of the processing method subsequent to FIGS. 4, 4A, 4B.

FIG. 6 is a cross-sectional view of the structure at a fabrication stage of the processing method subsequent to FIGS. 5, 5A, 5B.

FIG. 7 is a cross-sectional view of the structure at a fabrication stage of the processing method subsequent to FIG. 6.

### DETAILED DESCRIPTION

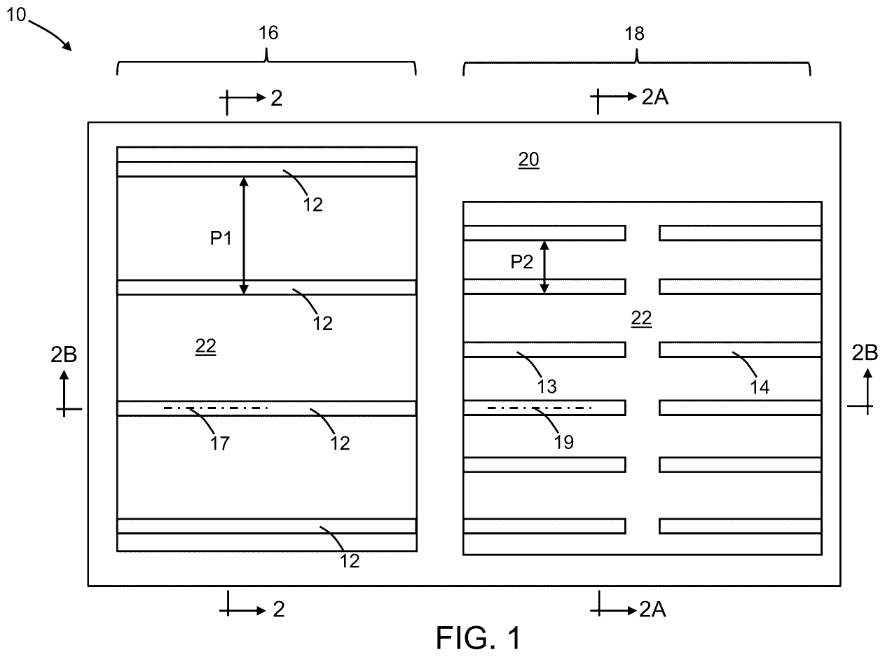

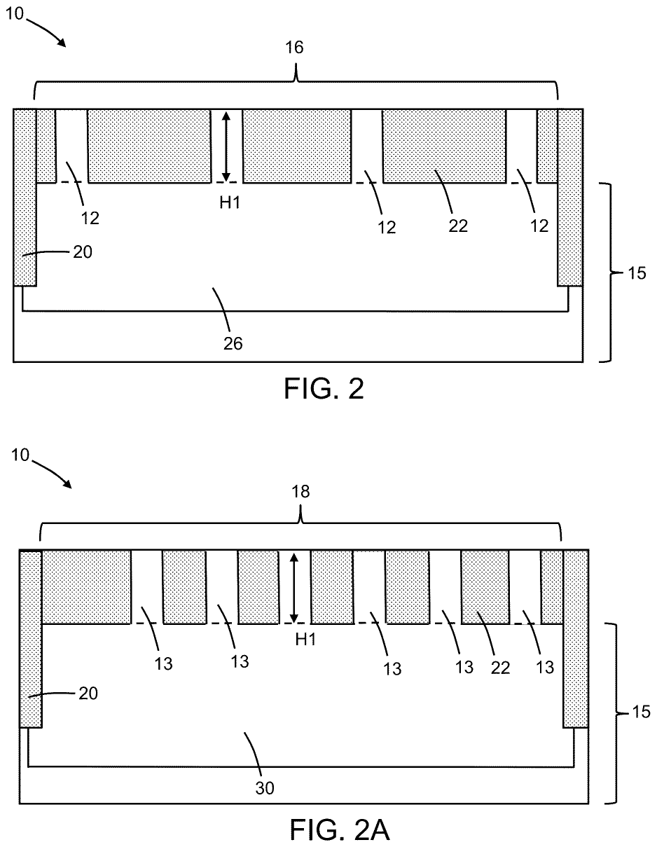

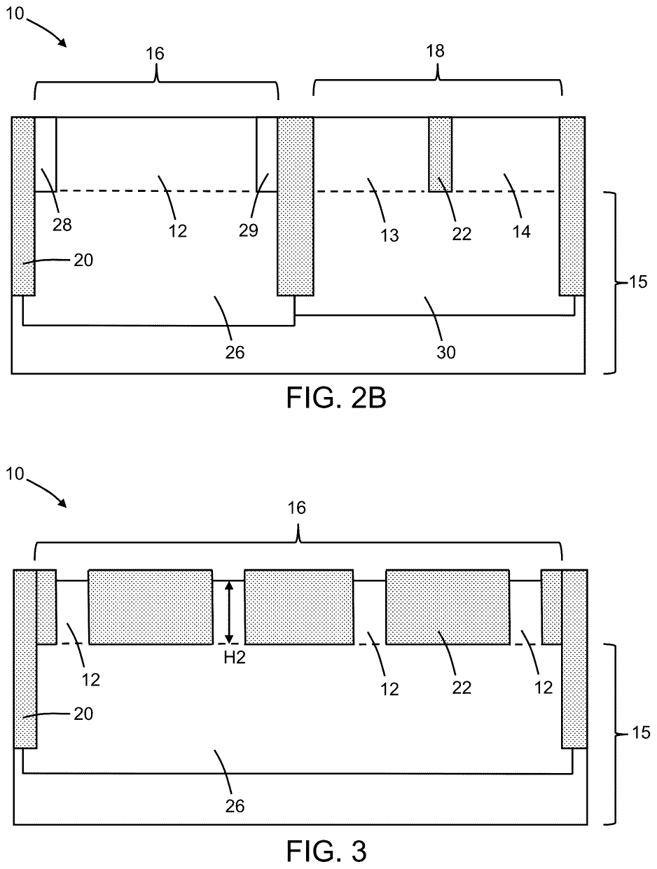

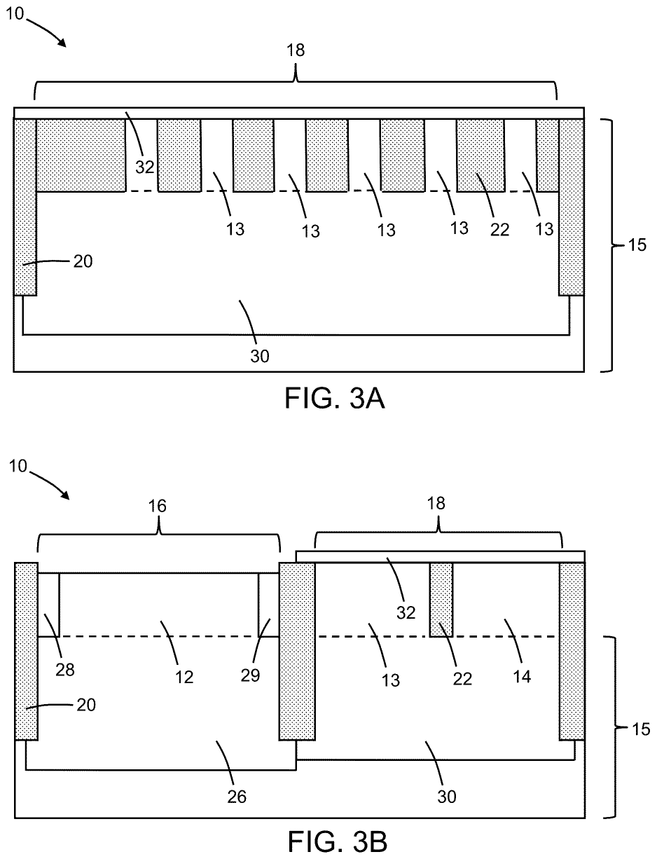

With reference to FIGS. 1, 2, 2A, 2B and in accordance with embodiments of the invention, a structure 10 includes fins 12, fins 13, fins 14, and a semiconductor substrate 15. The fins 12, the fins 13, the fins 14, and the semiconductor substrate 15 may be comprised of a single-crystal semiconductor material, such as single-crystal silicon. The semiconductor material of the semiconductor substrate 15 may be lightly doped with a concentration of a p-type dopant (e.g., boron). The fins 12, the fins 13, and the fins 14 may be patterned from the semiconductor material of the semiconductor substrate 15 using a self-aligned double patterning process. In an embodiment, the fins 13 may be arranged in a column of an array, the fins 14 may be arranged in a column of the array, and pairs of the fins 13, 14 may be arranged in rows of the array. In an embodiment, each of the fins 12 may have a longitudinal axis 17 that is aligned with a longitudinal axis 19 of one of the fins 13 and the adjacent fin 14. In an embodiment, the fins 12 may be formed with a pitch P1, and the fins 13 and the fins 14 may be formed with a pitch P2. In an embodiment, the pitch P1 may be greater than the pitch P2. In an embodiment, the pitch P1 may be equal to twice the pitch P2. As a numerical example, the pitch P1 may be about 96 nanometers, and the pitch P2 may be about 48 nanometers.

The semiconductor substrate 15 includes a device region 16 and a device region 18 that may be patterned after the fins 12, the fins 13, and the fins 14 are formed. The device region 18 may be disposed adjacent to the device region 16. The device region 16 includes the fins 12, and the device region 18 includes the fins 13, 14. Deep trench isolation regions 20 may be formed that surround the device regions 16, 18. Shallow trench isolation regions 22 may be formed in the spaces between the fin 12 and in the spaces between the fins 13, 14. In an embodiment, the deep trench isolation regions 20 and the shallow trench isolation regions 22 may be comprised of an oxide, such as silicon dioxide, that is an electrical insulator.

The fins 12, 13, 14 adjoin the semiconductor substrate 15 along an interface, as indicated by the dashed lines. The fins 12 and the fins 13, 14 have equal height dimensions H1 relative to the interface between the fins 12, 13, 14 and the semiconductor substrate 15. The fins 12 in the device region 16 may be used to form a fin-type field-effect transistor capable of operation at medium voltages in a range, for example, of 8 volts to 10 volts. The fins 13, 14 in the device region 18 may be used to form one or more fin-type field-effect transistors configured to operate at a low voltage.

A well 26 may be formed in a portion of the device region 16 of the semiconductor substrate 15. In an embodiment, the well 26 may contain a concentration of a p-type dopant, such as boron, to provide p-type conductivity. In an alternative embodiment, the well 26 may contain a concentration of an n-type dopant, such as phosphorus, to provide n-type conductivity. The well 26 may be formed by implanting ions, such as ions including the p-type dopant, with an implantation mask having an opening defining the intended location for the well 26 in the semiconductor substrate 15. The implantation conditions, such as ion species, dose, and kinetic energy, may be selected to tune the electrical and physical characteristics of the well 26. In an embodiment, the well 26 may extend to a greater depth in the semiconductor substrate 15 than the deep trench isolation regions 20.

Doped regions 28, 29 are formed in respective portions of the well 26 in the device region 16 of the semiconductor substrate 15. The doped regions 28, 29 may have an opposite conductivity type from the well 26. In an embodiment, the doped regions 28, 29 may contain a concentration of an n-type dopant, such as phosphorus, to provide n-type conductivity. The doped regions 28, 29 may be formed by implanting ions, such as ions including the n-type dopant, with an implantation mask having openings defining the intended locations for the doped regions 28, 29 in the semiconductor substrate 15. The implantation conditions, such as ion species, dose, and kinetic energy, may be selected to tune the electrical and physical characteristics of the doped regions 28, 29.

A well 30 may be formed in a portion of the device region 18 of the semiconductor substrate 15. In an embodiment, the well 30 may contain a concentration of an n-type dopant, such as phosphorus, to provide n-type conductivity. In an alternative embodiment, the well 30 may contain a concentration of a p-type dopant, such as boron, to provide p-type conductivity. The well 30 may be formed by implanting ions, such as ions including the n-type dopant, with an implantation mask having an opening defining the intended location for the well 30 in the semiconductor substrate 15. The implantation conditions, such as ion species, dose, and kinetic energy, may be selected to tune the electrical and physical characteristics of the well 30.

The well 30 may adjoin the well 26 along an interface across which the conductivity type changes. In an embodiment, the well 30 may extend to a greater depth in the semiconductor substrate 15 than the deep trench isolation regions 20. In an embodiment, the well 30 may extend to a shallower depth in the semiconductor substrate 15 than the well 26.

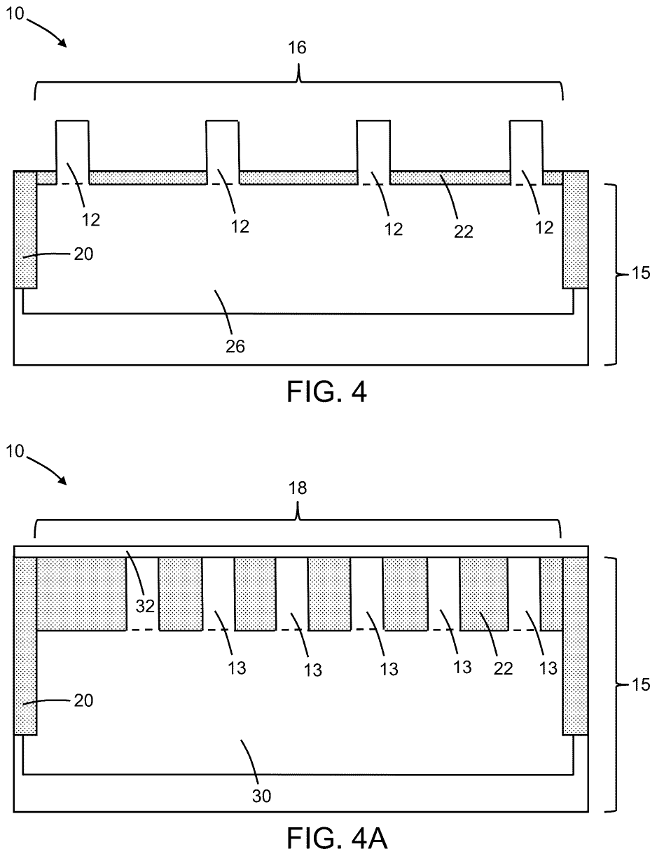

With reference to FIGS. 3, 3A, 3B and at a fabrication stage subsequent to FIGS. 2, 2A, 2B, a patterned hardmask 32 may be applied over the device region 18. The patterned hardmask 32 includes an opening that overlies the device region 16. The fins 12 are etched by an etching process selective to the deep trench isolation regions 20 and the shallow trench isolation regions 22 to shorten the height of the fins 12 to a height dimension H2, relative to the interface with the semiconductor substrate 15, that is less than the height dimensions H1 of the fins 13, 14 in device region 18. The height dimensions H1 of the fins 13, 14 are unchanged by the etching process.

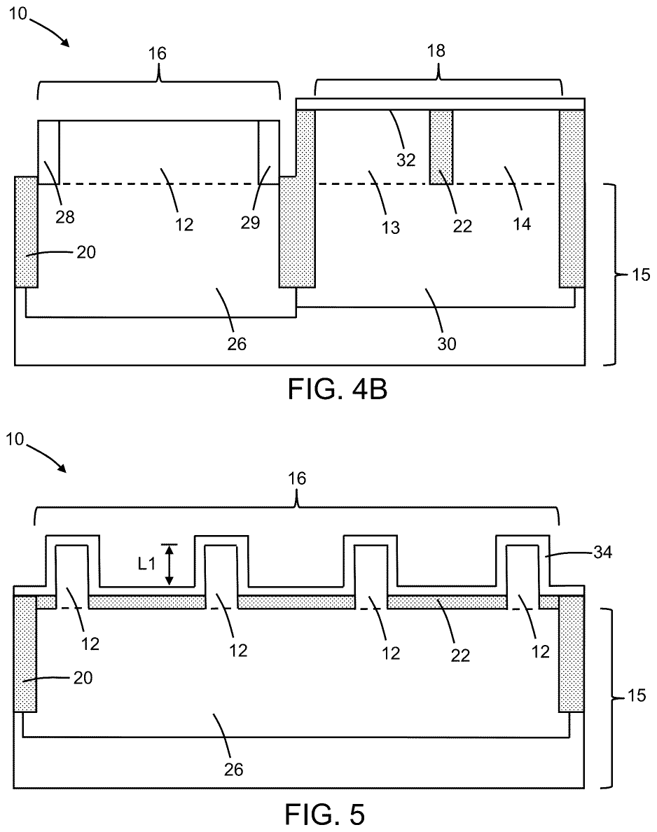

With reference to FIGS. 4, 4A, 4B and at a fabrication stage subsequent to FIGS. 3, 3A, 3B, the deep trench isolation regions 20 and the shallow trench isolation regions 22 in the device region 16 may be recessed by an etching process selective to the fins 12. The height dimensions H1 of the fins 13, 14 and the height dimension H2 of the fins 12 are unchanged by the etching process. The height dimension of the recessed deep trench isolation regions 20 and the recessed shallow trench isolation regions 22 is less than the height dimension H2 of the fins 12 such that active portions of the fins 12 project above the recessed deep trench isolation regions 20 and the recessed shallow trench isolation regions 22.

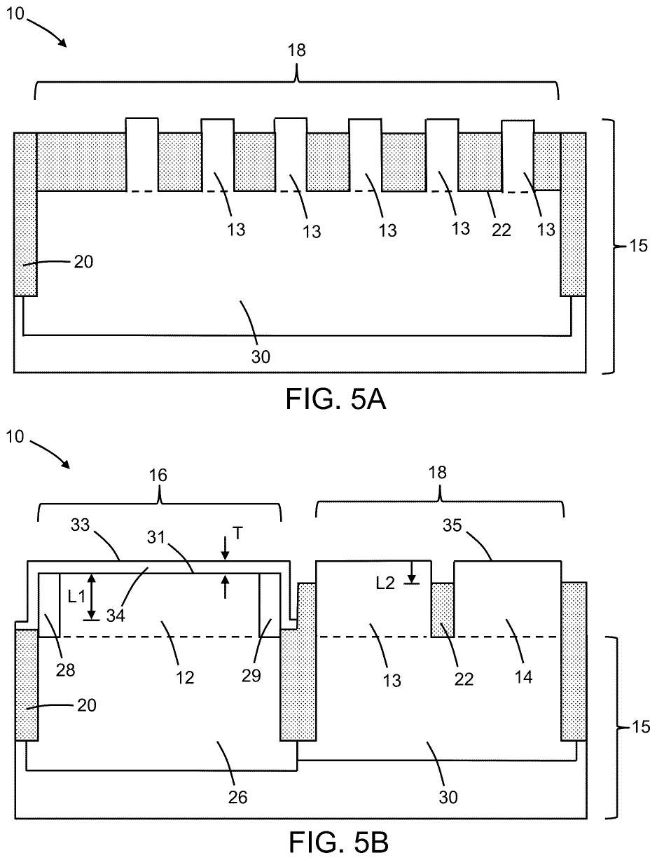

With reference to FIGS. 5, 5A, 5B and at a fabrication stage subsequent to FIGS. 4, 4A, 4B, a dielectric layer 34 may be applied that wraps around and overlaps with the fins 12, and that also overlaps with the shallow trench isolation regions 22 in the spaces between the fins 12. The dielectric layer 34 may be conformal with a uniform thickness. The dielectric layer 34 may be comprised of a dielectric material, such as an oxide like silicon dioxide, that is an electrical insulator. In an embodiment, the dielectric layer 34 may be comprised of a combination of a thermal silicon oxide formed by oxidation and a silicon oxide that is conformally deposited on the thermal silicon oxide. The patterned hardmask 32 may be stripped after forming the dielectric layer 34 to open the device region 18.

The deep trench isolation regions 20 and the shallow trench isolation regions 22 are recessed in the device region 18 by a selective etching process. Active portions of the fins 13 and active portions of the fins 14 project above the recessed deep trench isolation regions 20 and the recessed shallow trench isolation regions 22. The active portions of the fins 13 and portions of the fins 14 that project above the recessed deep trench isolation regions 20 and the recessed shallow trench isolation regions 22 may be coated by a thin dielectric layer (not shown) comprised of an oxide, such as silicon dioxide, that is an electrical insulator.

The active portions of the fins 12 have a length L1 relative to a top surface 31 that is a fraction of the height H1. The active portions of the fins 13, 14 have a length L2 that is a fraction of the height H2. In an embodiment, the length L1 is greater than the length L2. In an embodiment, the length L1 may be about 60 nanometers, and the length L2 may be about 40 nanometers.

The dielectric layer 34 includes portion that overlaps with a top surface 31 of each fin 12. In an embodiment, the dielectric layer 34 may have a thickness T that is equal to a difference between the height H1 and the height H2. As a result, the thickness T of the portion of the dielectric layer 34 on the top surface 31 compensates for the difference between the height H1 and the height H2 and permits the fin-overlapping portion of the dielectric layer 34 to have a top surface 33 that is planar or substantially planar with the top surfaces 35 of the fins 13, 14.

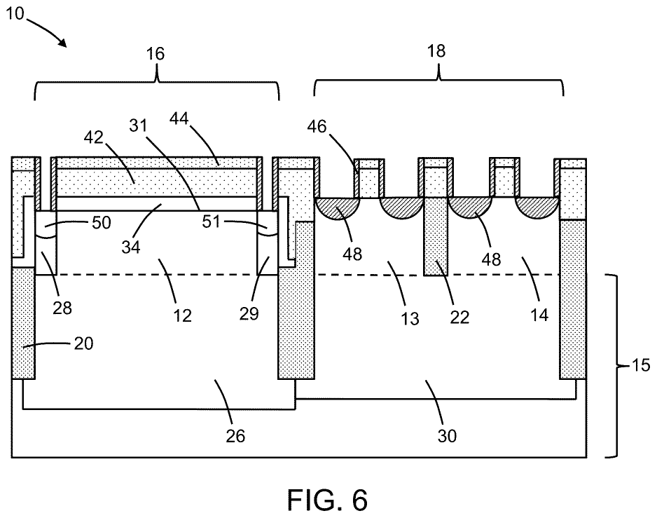

With reference to FIG. 6 and at a fabrication stage subsequent to FIGS. 5, 5A, 5B, a layer 42 and a layer 44 may be sequentially deposited and patterned by lithography and etching processes to form openings extending to the device regions 16, 18. The layer 42 may be comprised of, for example, polysilicon, and the layer 44 may be comprised of, for example, silicon nitride that operates as a hardmask when the layer 42 is patterned. The patterned layers 42, 44 may include a portion that extends transversely across the fins 12, and portions that extend transversely across the fins 13, 14. In an embodiment, the patterned layers 42, 44 may represent a sacrificial layer stack that is removed and replaced later in the process flow. Portions of the dielectric layer 34 revealed by the openings in the patterned layers 42, 44 may be removed by an etching process to expose portions of the top surface 31 of each fin 12 overlying the doped regions 28, 29. Spacers 46 may be positioned adjacent to the sidewalls of the patterned layers 42, 44. The spacers 46 may be comprised of one or more dielectric material that are electrical insulators.

Source/drain regions 48 may be formed inside cavities that are patterned in each of the fins 13 and cavities that are patterned each of the fins 14 by lithography and etching processes. As used herein, the term “source/drain region” means a region of semiconductor material that can function as either a source or a drain of a field-effect transistor. The source/drain regions 48, which are laterally positioned in the device region 18 between the layer stacks including the patterned layers 42, 44, may be comprised of a semiconductor material, such as silicon or silicon-germanium. The semiconductor material of the source/drain regions 48 may be grown by an epitaxial growth process from the surfaces of the fins 13, 14 bordering the cavities and may be in situ doped during epitaxial growth with a concentration of a dopant. The semiconductor material of the source/drain regions 48 may be doped with an n-type dopant, such as phosphorus, that provides n-type conductivity. In an alternative embodiment, the semiconductor material of the source/drain regions 48 may be doped with a p-type dopant, such as boron, that provides p-type conductivity.

Source/drain regions 50, 51 may be formed in peripheral portions of each fin 12. The source/drain regions 50, 51, which are arranged inside the respective boundaries of the doped regions 28, 29, extend in each fin 12 to a shallower depth than the doped regions 28, 29. In an embodiment, the source/drain regions 50, 51 may contain a concentration of an n-type dopant, such as phosphorus, to provide n-type conductivity. In an alternative embodiment, the source/drain regions 50, 51 may contain a concentration of a p-type dopant, such as boron, to provide p-type conductivity. In an embodiment, the doped regions 28, 29 and the source/drain regions 50, 51 may contain the same type of dopant. The source/drain regions 50, 51 may be formed by implanting ions, such as ions including the n-type dopant, using the patterned layers 42, 44 as an implantation mask. The implantation conditions, such as ion species, dose, and kinetic energy, may be selected to tune the electrical and physical characteristics of the source/drain regions 50, 51, which may be more heavily doped than the doped regions 28, 29. In an alternative embodiment, cavities may be patterned in the fins 12 and the source/drain regions 50, 51 may be formed by epitaxial growth inside the cavities.

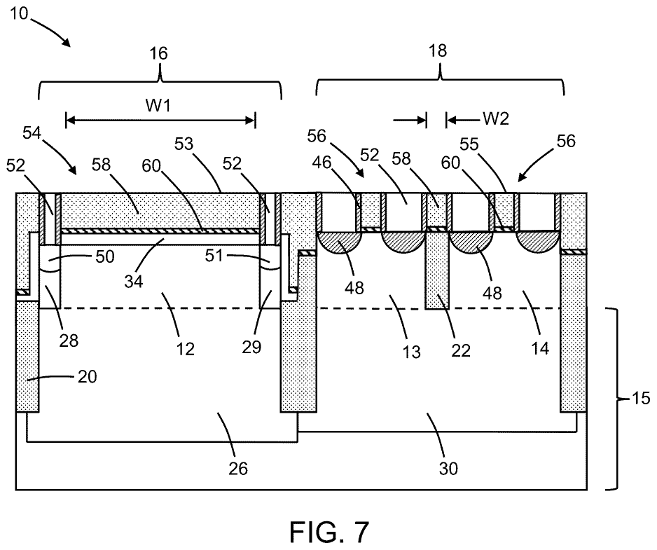

With reference to FIG. 7 and at a fabrication stage subsequent to FIG. 6, a dielectric layer 52 may be deposited and planarized, the layers 42, 44 may be removed by an etching process, a gate structure 54 may be formed in the device region 16, and gate structures 56 may be formed in the device region 18. Each of that gate structures 54, 56 may include a conductor layer 58 comprised of one or more metals, such as a work function metal and tungsten, and a dielectric layer 60 comprised of an electrical insulator, such as a high-k dielectric material like hafnium dioxide. Each fin 12 includes a channel region beneath the gate structure 54 and laterally between the source/drain region 50 and the source/drain region 51. Trench silicide contacts (not shown) may be formed in the dielectric layer 52 that physically and electrically contact the source/drain regions 50, 51 of the fin-type field-effect transistor in the device region 16 and the source/drain regions 48 of the fin-effect transistor formed in the device region 18.

The fin-effect transistor in the device region 16 has a gate dielectric layer with a thickness given by the sum of the thickness of the dielectric layer 34 and the thickness of the dielectric layer 60. The fin-effect transistor in the device region 18 has a gate dielectric layer with a thickness given by the thickness of the dielectric layer 60. As a consequence, the fin-effect transistor in the device region 16 has a thicker gate dielectric layer than the fin-effect transistor in the device region 18.

The gate structure 54 has a top surface 53, and each of the gate structures 56 has a top surface 55 that may be substantially coplanar, or coplanar, with the top surface 53 of the gate structure 54. The width W1 of the top surface 53 of the gate structure 54 may be greater than the width W2 of the top surface 55 of each gate structure 56. The coplanarity may result from the replacement metal gate process used to form the gate structures 54, 56. In that regard, the gate structure 54 of the fin-type field-effect transistor formed in the device region 16 as part of a shared process flow that also forms the gate structures 56 of the fin-type field-effect transistor in the device region 18.

The recessing of the fins 12 to a height H2 that is shorter than the height H1 of the fins 13, 14 permits the integration of the dielectric layer 34, which wraps around the fins 12, while maintaining the coplanarity of the top surface 53 of the gate structure 54 and the top surfaces 55 of the gate structures 56. In an embodiment, the difference between the height H1 and the height H2 may be equal or substantially equal to the thickness T of the dielectric layer 34.

The dielectric layer 34 provides a portion of a gate dielectric layer for the fin-type field-effect transistor that is formed in the device region 16. The gate dielectric for the field-effect transistor that is formed in the device region 16 also includes a contribution from the dielectric layer 60 that overlies the dielectric layer 34.

The fin-type field-effect transistor capable of operating at medium voltages formed in the device region 16 may conserve chip area and operate at lower power in comparison with planar field-effect capable of operating at medium voltages. The medium-voltage fin-type field-effect transistor formed using the fins 12 in the device region 16 is compatible with the low-voltage fin-type field-effect transistors formed using the fins 13, 14 in the device region 18. For example, the medium-voltage fin-type field-effect transistor may be formed in the device region 16 by the integrated process flow without interruption or adjustment to the formation of the low-voltage fin-type field-effect transistors in the device region 18. The utilization of the conductor layer 58 and the dielectric layer 60 to form the gate structure 54 enable threshold voltage tuning by adjust the work function of the gate structure 54.

In an alternative embodiment, the structure 10 may further includes a high-voltage semiconductor device as described in U.S. application Ser. No. 18/907,840, which is hereby incorporated by reference in its entirety herein.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value or precise condition as specified. In embodiments, language of approximation may indicate a range of +/−10% of the stated value(s) or the stated condition(s).

References herein to terms such as “vertical”, “horizontal”, etc. are made by way of example, and not by way of limitation, to establish a frame of reference. The term “horizontal” as used herein is defined as a direction or a plane parallel to a conventional plane of a semiconductor substrate, regardless of its actual three-dimensional spatial orientation. The terms “vertical” and “normal” refer to a direction or plane in the frame of reference perpendicular to the horizontal plane, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or “directly contacting” another feature if intervening features are absent. A feature may be “indirectly on” or in “indirect contact” with another feature if at least one intervening feature is present. A feature may “overlie” another feature if a feature is positioned “over” another feature. Different features may “overlap” if a feature extends over, and covers a part of, another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a first field-effect transistor including a first semiconductor fin, a first source/drain region, a second source/drain region, a first gate that wraps around the first semiconductor fin, and a first gate dielectric layer between the first gate and the first semiconductor fin, the first gate dielectric layer including a first dielectric layer and a second dielectric layer on the first dielectric layer, and the first gate laterally between the first source/drain region and the second source/drain region.

2. The structure of claim 1 wherein the first dielectric layer has a first thickness, the second dielectric layer has a second thickness, and the first thickness is greater than the second thickness.

3. The structure of claim 1 wherein the first dielectric layer comprises a first dielectric material, and the second dielectric layer comprises a second dielectric material different from the first dielectric material.

4. The structure of claim 3 wherein the second dielectric material is a high-k dielectric material.

5. The structure of claim 1 wherein the first gate comprises a work function metal.

6. The structure of claim 1 wherein the first semiconductor fin includes a first active portion, the first gate that wraps around the first active portion of the first semiconductor fin, and further comprising:
a second field-effect transistor including a second semiconductor fin and a second gate, the second semiconductor fin having a second active portion, and the second gate wraps around the second active portion of the second semiconductor fin.

7. The structure of claim 6 wherein the first gate has a first top surface, and the second gate has a second top surface that is substantially coplanar with the first top surface.

8. The structure of claim 6 the first gate has a first width, the second gate has a second width, and the first width is greater than the second width.

9. The structure of claim 6 wherein the first gate and the second gate comprise a work function metal.

10. The structure of claim 6 wherein the first active portion has a first length, the second active portion has a second length, and the first length is greater than the second length.

11. The structure of claim 6 further comprising:
a semiconductor substrate,
wherein the first semiconductor fin and the second semiconductor fin adjoin the semiconductor substrate along an interface.

12. The structure of claim 11 wherein the first semiconductor fin has a first top surface, the second semiconductor fin has a second top surface, the first top surface is spaced from the interface by a first height, the second top surface is spaced from the interface by a second height, and the second height is greater than the first height.

13. The structure of claim 12 wherein the first dielectric layer has a thickness on the first top surface of the first semiconductor fin, and the thickness is substantially equal to a difference between the first height and the second height.

14. The structure of claim 12 wherein the first dielectric layer has a thickness on the first top surface of the first semiconductor fin, and the thickness is equal to a difference between the first height and the second height.

15. The structure of claim 6 wherein the first semiconductor fin has a first longitudinal axis, the second semiconductor fin has a second longitudinal axis, and the first longitudinal axis is aligned with the second longitudinal axis.

16. The structure of claim 6 wherein the first field-effect transistor has a third semiconductor fin that is arranged with a first pitch relative to the first semiconductor fin, the second field-effect transistor has a fourth semiconductor fin that is arranged with a second pitch relative to the second semiconductor fin, and the first pitch is greater than the second pitch.

17. The structure of claim 6 wherein the first field-effect transistor has a third semiconductor fin that is arranged with a first pitch relative to the first semiconductor fin, the second field-effect transistor has a fourth semiconductor fin that is arranged with a second pitch relative to the second semiconductor fin, and the first pitch is equal to twice the second pitch.

18. The structure of claim 6 wherein the first dielectric layer has a first thickness, the second dielectric layer has a second thickness, the first thickness is greater than the second thickness, the second field-effect transistor includes a second gate dielectric layer between the second gate and the second semiconductor fin, and the second dielectric layer has a third thickness equal to the second thickness.

19. The structure of claim 1 wherein the first source/drain region and the second source/drain region are arranged inside the first semiconductor fin.

20. A method comprising:
forming a field-effect transistor including a semiconductor fin, a first source/drain region, a second source/drain region, a gate that wraps around the semiconductor fin, and a gate dielectric layer between the gate and the semiconductor fin,
wherein the gate dielectric layer includes a first dielectric layer and a second dielectric layer on the first dielectric layer, and the gate is laterally positioned between the first source/drain region and the second source/drain region.
